(19) United States
(12) Patent Application Publication
(10) Pub. No.: US 2023/0108732 A1
(43) Pub. Date: Apr. 6, 2023

(54) Methods Of Selectively Forming Metal-Containing Films

(71) Applicant: MERCK PATENT GMBH, Darmstadt (DE)

(72) Inventors: Joby ELDO, Andover, MA (US); Jacob WOODRUFF, Lexington, MA (US); Shawn Sungeun HONG, Westford, MA (US); Ravindra KANJOLIA, North Andover, MA (US); Charith NANAYAKKARA, Haverhill, MA (US); Charles DEZELAH, Haverhill, MA (US)

(21) Appl. No.: 17/796,559

(22) PCT Filed: Feb. 1, 2021
(86) PCT No.: PCT/EP2021/052259

§ 371 Date: Jul. 29, 2022

Related U.S. Application Data
(60) Provisional application No. 62/970,014, filed on Feb. 4, 2020.

(51) Int. Cl. C23C 16/04; C23C 16/18; C23C 16/455; B05D 1/00; C23C 16/02; H01L 21/02

(52) U.S. Cl. CPC C23C 16/04; C23C 16/18; C23C 16/45553; B05D 1/60; C23C 16/0272; H01L 21/02181; H01L 21/02304; H01L 21/0228

(57) ABSTRACT

Methods of forming metal-containing films are provided. The methods include forming a blocking layer, for example, on a first substrate surface, by a first deposition process and forming the metal-containing film, for example, on a second substrate surface, by a second deposition process.

### FIELD OF THE INVENTION

The present technology relates generally to deposition methods, particularly methods for selective metal-containing film growth on a substrate surface.

### BACKGROUND

Thin films, and in particular thin metal-containing films, have a variety of important applications, such as in nanotechnology and the fabrication of semiconductor devices. Examples of such applications include high-refractive index optical coatings, corrosion-protection coatings, photocatalytic self-cleaning glass coatings, biocompatible coatings, dielectric capacitor layers and gate dielectric insulating films in field-effect transistors (FETs), capacitor electrodes, gate electrodes, adhesive diffusion barriers, and integrated circuits. Metallic thin films and dielectric thin films are also used in microelectronics applications, such as the high-κ dielectric oxide for dynamic random access memory (DRAM) applications and the ferroelectric perovskites used in infrared detectors and non-volatile ferroelectric random access memories (NV-FeRAMs).

Various precursors may be used to form metal-containing thin films and a variety of deposition techniques can be employed. Such techniques include reactive sputtering, ion-assisted deposition, sol-gel deposition, chemical vapor deposition (CVD) (also known as metalorganic CVD or MOCVD), and atomic layer deposition (ALD) (also known as atomic layer epitaxy). CVD and ALD processes are increasingly used as they have the advantages of enhanced compositional control, high film uniformity, and effective control of doping.

CVD is a chemical process whereby precursors are used to form a thin film on a substrate surface. In a typical CVD process, the precursors are passed over the surface of a substrate (e.g., a wafer) in a low pressure or ambient pressure reaction chamber. The precursors react and/or decompose on the substrate surface creating a thin film of deposited material. Volatile by-products are removed by gas flow through the reaction chamber. The deposited film thickness can be difficult to control because it depends on coordination of many parameters such as temperature, pressure, gas flow volumes and uniformity, chemical depletion effects, and time.

ALD is also a method for the deposition of thin films. It is a self-limiting, sequential, unique film growth technique based on surface reactions that can provide precise thickness control and deposit conformal thin films of materials provided by precursors onto surfaces substrates of varying compositions. In ALD, the precursors are separated during the reaction. The first precursor is passed over the substrate surface producing a monolayer on the substrate surface. Any excess unreacted precursor is pumped out of the reaction chamber. A second precursor is then passed over the substrate surface and reacts with the first precursor, forming a second monolayer of film over the first-formed monolayer of film on the substrate surface. This cycle is repeated to create a film of desired thickness.

However, with the continual decrease in the size of microelectronic components, such as semi-conductor devices, several technical challenges remain thereby increasing the need for improved thin film technologies. In particular, microelectronic components may include patterning, e.g., to form a conductive pathway or to form interconnections. Typically, patterning is achieved via etching and lithography techniques, but such techniques can be challenging as the demand for patterning complexity increases. Accordingly, there exists significant interest in the development of thin film deposition methods, that can selectively grow a film on one or more substrates and achieve improved patterning on a substrate.

### SUMMARY

According to one aspect, a method of forming a metal-containing film is provided. The method includes forming a blocking layer on a first substrate surface by a first vapor phase deposition process or a first liquid phase deposition process. The first vapor phase deposition process includes vaporizing a compound corresponding in structure to Formula (I):

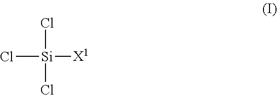

wherein X¹ is R¹ or R²R³, wherein R¹ is a C₁-C₂₀-alkyl, optionally substituted with one or more trichlorosilyl group, R² is a C₁-C₂₀-alkylene group optionally substituted with one or more halogen, and R³ is selected from the group consisting of a nitrile group, an ethenyl group, a halogen, a triflouromethyl group, an acetoxy group, a methoxyethoxy group, and a phenoxy group. The first liquid phase deposition process includes contacting the first substrate surface with a solution including the compound corresponding in structure to Formula (I). The method further includes forming the metal-containing film on a second substrate surface by a second deposition process. The second deposition process includes vaporizing at least one metal complex. The first substrate surface can include a dielectric material or a metal oxide and the second substrate surface can include a metal material.

According to another aspect, another method of forming a metal-containing film is provided. The method includes forming a blocking layer on a first portion of a substrate by a first vapor phase deposition process or a first liquid phase deposition process. The first vapor phase deposition process includes vaporizing a compound corresponding in structure to Formula (I):

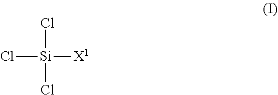

wherein X¹ is R¹ or R²R³, wherein R¹ is a C₁-C₂₀-alkyl, optionally substituted with one or more trichlorosilyl group, R² is a C₁-C₂₀-alkylene group optionally substituted with one or more halogen, and R³ is selected from the group consisting of a nitrile group, an ethenyl group, a halogen, a triflouromethyl group, an acetoxy group, a methoxyethoxy group, and a phenoxy group. The first liquid phase deposition process comprises contacting the first portion of the substrate with a solution comprising the compound corresponding in structure to Formula (I). The method further includes forming the metal-containing film on a second portion of the substrate by a second deposition process. The second deposition process includes vaporizing at least one metal complex. The first portion of the substrate can include a dielectric material or a metal oxide and the second portion of the substrate can include a metal material.

Other embodiments, including particular aspects of the embodiments summarized above, will be evident from the detailed description that follows.

### BRIEF DESCRIPTION OF THE DRAWINGS

FIG. 1A illustrates details of a blocking layer and a metal-containing film according to certain aspects of the present disclosure.

FIG. 1B illustrates details of a blocking layer and a metal-containing film according to certain alternate aspects of the present disclosure.

### DETAILED DESCRIPTION

Before describing several exemplary embodiments of the present technology, it is to be understood that the technology is not limited to the details of construction or process steps set forth in the following description. The present technology is capable of other embodiments and of being practiced or being carried out in various ways. It is also to be understood that the metal complexes and other chemical compounds may be illustrated herein using structural formulas which have a particular stereochemistry. These illustrations are intended as examples only and are not to be construed as limiting the disclosed structure to any particular stereochemistry. Rather, the illustrated structures are intended to encompass all such metal complexes and chemical compounds having the indicated chemical formula.

Applicants have discovered methods of performing deposition, which can selectively form a metal-containing film. In particular, the methods described herein can form a blocking layer on a first substrate surface or a first portion of a surface by a first deposition process, for example, a first vapor phase deposition or a first liquid phase deposition, and a metal-containing film on a second substrate surface or a second portion of the surface by a second deposition process. It was discovered that a blocking layer may deposited on metal-containing substrate, and this blocking layer can substantially block or inhibit growth of a metal-containing film on the blocking layer while allowing deposition of the metal-containing film on a dielectric material-containing substrate and/or a metal oxide-containing substrate. Advantageously, the methods described herein can allow for selective dielectric-on-dielectric deposition. Additionally, the methods described herein can allow for delivery of the blocking layer via a vapor phase method, which can use the same equipment utilized for delivery of the metal complex.

### I. Definitions

For purposes of this invention and the claims hereto, the numbering scheme for the Periodic Table Groups is according to the IUPAC Periodic Table of Elements.

The term “and/or” as used in a phrase such as “A and/or B” herein is intended to include “A and B”, “A or B”, “A”, and “B”.

The terms “substituent”, “radical”, “group”, and “moiety” may be used interchangeably.

As used herein, the terms “metal-containing complex” (or more simply, “complex”) and “precursor” are used interchangeably and refer to a metal-containing molecule or compound which can be used to prepare a metal-containing film, for example, by a vapor deposition process such as, for example, ALD or CVD. The metal-containing complex may be deposited on, adsorbed to, decomposed on, delivered to, and/or passed over a substrate or surface thereof, as to form a metal-containing film.

As used herein, the term “metal-containing film” includes not only an elemental metal film as more fully defined below, but also a film which includes a metal along with one or more elements, for example a metal oxide film, metal nitride film, metal silicide film, a metal carbide film and the like. As used herein, the terms “elemental metal film” and “pure metal film” are used interchangeably and refer to a film which consists of, or consists essentially of, pure metal. For example, the elemental metal film may include 100% pure metal or the elemental metal film may include at least about 70%, at least about 80%, at least about 90%, at least about 95%, at least about 96%, at least about 97%, at least about 98%, at least about 99%, at least about 99.9%, or at least about 99.99% pure metal along with one or more impurities. Unless context dictates otherwise, the term “metal film” shall be interpreted to mean an elemental metal film.

As used herein, the term “vapor phase deposition process” is used to refer to any type of vapor deposition technique, including but not limited to, CVD and ALD. In various embodiments, CVD may take the form of conventional (i.e., continuous flow) CVD, liquid injection CVD, or photo-assisted CVD. CVD may also take the form of a pulsed technique, i.e., pulsed CVD. ALD is used to form a metal-containing film by vaporizing and/or passing at least one metal complex disclosed herein over a substrate surface. For conventional ALD processes see, for example, George S. M., et al. J. Phys. Chem., 1996, 100, 13121-13131. In other embodiments, ALD may take the form of conventional (i.e., pulsed injection) ALD, liquid injection ALD, photo-assisted ALD, plasma-assisted ALD, or plasma-enhanced ALD. The term “vapor deposition process” further includes various vapor deposition techniques described in Chemical Vapour Deposition: Precursors, Processes, and Applications; Jones, A. C.; Hitchman, M. L., Eds. The Royal Society of Chemistry: Cambridge, 2009; Chapter 1, pp 1-36.

As used herein, the term “liquid phase deposition process” refers to any type of liquid deposition techniques wherein materials and/or compounds are deposited on a substrate via a liquid phase, where the liquid is a solution or a dispersion. Exemplary liquid phase deposition processes include spin coating, blade coating, spray coating, roll coating, extrusion coating, rod coating, dip coating, and the like.

As used herein, the terms “selective growth,” “selectively grown” and “selectively grows” may be used synonymously and refer to film growth on at least a portion of a second substrate surface (or second portion of a substrate) and substantially no film growth on a first substrate surface (or first portion of a substrate) and/or or on a blocking layer as well as more film growth on at least a portion of the second substrate surface (or second portion of the substrate) compared to film growth on a first substrate surface (or first portion of a substrate) and/or on a blocking layer. With respect to more than one substrate, the terms “selective growth” “selectively grown” and “selectively grows” also encompass film growth on a first substrate and substantially no film growth on a second substrate (or a third substrate, or fourth substrate or a fifth substrate, etc.) as well as more film growth on the first substrate than on the second substrate (or a third substrate, or fourth substrate or a fifth substrate, etc.).

The term “alkyl” (alone or in combination with another term(s)) refers to a saturated hydrocarbon chain of 1 to about 25 carbon atoms in length, such as, but not limited to, methyl, ethyl, propyl, butyl, pentyl, hexyl, heptyl, octyl, decyl, and so forth. The alkyl group may be straight-chain or branched-chain. “Alkyl” is intended to embrace all structural isomeric forms of an alkyl group. For example, as used herein, propyl encompasses both n-propyl and isopropyl; butyl encompasses n-butyl, sec-butyl, isobutyl and tert-butyl; pentyl encompasses n-pentyl, tert-pentyl, neopentyl, isopentyl, sec-pentyl and 3-pentyl. Further, as used herein, “Me” refers to methyl, “Et” refers to ethyl, “Pr” refers to propyl, “i-Pr” refers to isopropyl, “Bu” refers to butyl, “t-Bu” refers to tert-butyl, and “Np” refers to neopentyl. In some embodiments, alkyl groups are C₁-C₅₋ or C₁-C₄-alkyl groups.

The term “alkylene” refers to a divalent alkyl moiety containing 1 to 20 carbon atoms (i.e. C₁-C₂₀alkylene) in length and meaning the alkylene moiety is attached to the rest of the molecule at both ends of the alkyl unit. For example, alkylenes include, but are not limited to, —CH₂—, —CH₂CH₂—, —CH(CH₃)CH₂—, —CH₂CH₂CH₂—, etc. The alkylene group may be linear or branched.

The term “alkoxy” refers to —O-alkyl containing from 1 to about 8 carbon atoms. The alkoxy may be straight-chain or branched-chain. Non-limiting examples include methoxy, ethoxy, propoxy, butoxy, isobutoxy, tert-butoxy, pentoxy and hexoxy.

### II. Methods of Forming a Metal-Containing Film

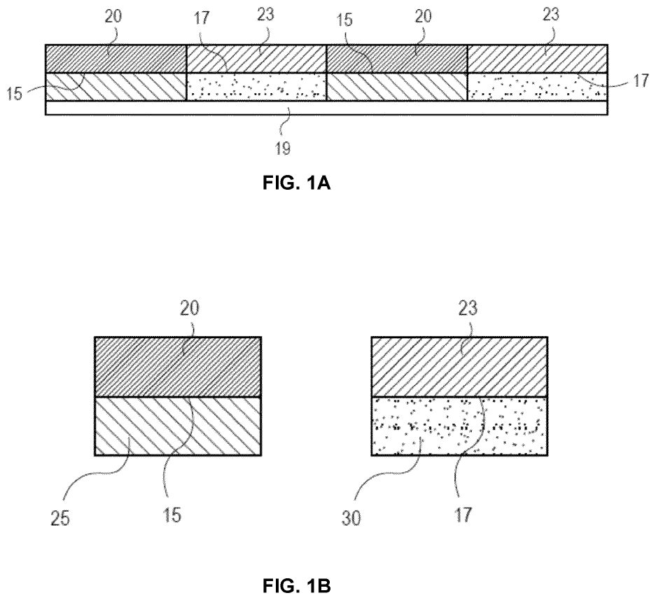

Methods of forming metal-containing films, for example, where the metal-containing film is selectively grown are provided herein. In various aspects, as illustrated in FIG. 1A, the method may include forming a blocking layer 20 on a first substrate surface 15 by a first deposition process. The method may further include forming a metal-containing film 23 on a second substrate surface 17 by a second deposition process. As shown in FIG. 1A the first substrate surface 15 and the second substrate surface 17 may be present on a single substrate 19, i.e., the same substrate. For example, when a single substrate 19 is used, the first substrate surface 15 can be considered a first portion 15 of substrate 19 and the second substrate surface 17 can be considered a second portion 17 of substrate 19. Alternatively, as illustrated in FIG. 1B, the first substrate surface 15 and the second substrate surface 17 may be present on different substrates, for example, a first substrate 25 and a second substrate 30, respectively.

The first substrate surface 15 (or first portion 15) can comprise a dielectric material, a metal oxide material, or a combination thereof. The dielectric material can be a low-κ dielectric or a high-κ dielectric. Examples of suitable dielectric materials include, but are not limited to SiO_{2,} SiN, and a combination thereof. Examples of suitable metal oxide materials include, but are not limited to HfO₂, ZrO₂, SiO₂, Al₂O₃, and combinations thereof. The second substrate surface 17 (or second portion 17) can comprise a metal material. Examples of suitable metal materials include, but are not limited to tungsten (W), cobalt (Co), copper (Cu), and combinations thereof. In some embodiments, the metal material may comprise Co, Cu, or a combination thereof. In a particular embodiment, the metal material may comprise Cu.

In any embodiment, the first deposition process may include a first vapor phase deposition process, a first liquid phase deposition process, or a combination thereof. The first vapor phase deposition process may include vaporizing a compound corresponding in structure to Formula I:

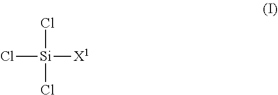

wherein X¹ can be R¹ or R²R³. R¹ can be a C₁-C₂₀-alkyl, optionally substituted with one or more

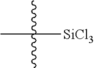

(a trichlorosilyl group). R² can be a C₁-C₂₀-alkylene group optionally substituted with one or more halogen (e.g., F, Cl, Br, etc.). R³ can selected from the group consisting of

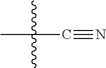 [SMILES: *C#N]

(a nitrile group),

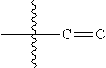 [SMILES: *C=C]

(an ethenyl group), a halogen (e.g., F, Cl, Br, etc.),

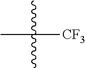 [SMILES: *C(F)(F)F]

(a triflouromethyl group),

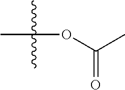 [SMILES: *OC(C)=O]

(an acetoxy group),

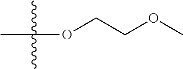 [SMILES: *OCCOC]

(a methoxyethoxy group), and

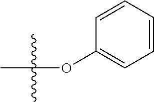 [SMILES: *Oc1ccccc1]

(a phenoxy group).

The compound corresponding in structure to Formula I may be vaporized in the presence of a substrate (e.g., first substrate surface 15, second substrate surface 17, substrate 19, first substrate 25, second substrate 30) and/or the vaporized compound corresponding in structure to Formula I may be exposed to a substrate (e.g., first substrate surface 15, second substrate surface 17, substrate 19, first substrate 25, second substrate 30). In any embodiment, the first liquid phase deposition process may include contacting a substrate surface (e.g., first substrate surface 15, second substrate surface 17, substrate 19, first substrate 25, second substrate 30) with a solution comprising the compound corresponding in structure to Formula (I).

In some embodiments, X¹ can be R¹, wherein R¹ can be a C₁-C₂₀-alkyl, optionally substituted with one or more trichlorosilyl group, for example, 1 to 12 trichlorosilyl groups, 1 to 8 trichlorosilyl groups, 1 to 4 trichlorosily groups, or 1 to 2 trichlorosilyl groups. In some embodiments, R¹ can be a C₁-C₁₅-alkyl, a C₁-C₁₂-alkyl, C₁-C₁₀-alkyl, a C₁-C₈-alkyl, a C₁-C₄-alkyl, or a C₁-C₂-alkyl, each optionally substituted with one or more of a trichlorosilyl group. The alkyl group may be straight-chained or branch. In particular, the alkyl is straight-chained.

In some embodiments, X¹ can be R²R³, wherein R² can be a C₁-C₂₀-alkylene group, a C₁-C₁₅-alkylene group, a C₁-C₁₂-alkylene group, a C₁-C₁₀-alkylene group, a C₁-C₈-alkylene group, or a C₁-C₄-alkylene group, each optionally substituted with one or more halogen (e.g., F, Cl, Br, etc.).

In some embodiments, X¹ can be R²R³, wherein R² can be a C₁-C₁₂-alkylene group, optionally substituted with 1 to 10 halogens (e.g., F, Cl, Br, etc.) and R³ can be selected from the group consisting of a nitrile group, an ethenyl group, a halogen, a triflouromethyl group, an acetoxy group, a methoxyethoxy group, and a phenoxy group.

In any embodiment, compounds corresponding in structure to Formula (I) are shown below in Table 1.

TABLE 1

| | Name | Structure |
|---|---|---|
| 1 | n-octyltrichlorosilane | 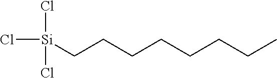 |
| 2 | dodecyltrichlorosilane | 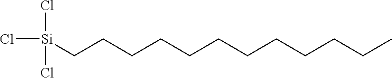 [SMILES: CCCCCCCCCCCC[Si](Cl)(Cl)Cl] |
| 3 | 11-cyanoundecyltrichlorosilane | 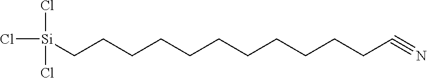 [SMILES: N#CCCCCCCCCCCC[Si](Cl)(Cl)Cl] |
| 4 | 11-acetoxyundecyltrichlorosilane | 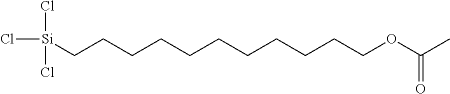 [SMILES: CC(=O)OCCCCCCCCCCC[Si](Cl)(Cl)Cl] |
| 5 | (tridecafluoro-1,1,2,2- tetrahydrooxtyl)trichlorosilane | 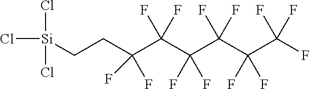 [SMILES: FC(F)(F)C(F)(F)C(F)(F)C(F)(F)C(F)(F)C(F)(F)CC[Si](Cl)(Cl)Cl] |
| 6 | 10-undecenyltrichlorosilane | 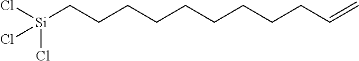 |
| 7 | 11-bromoundecyltrichlorosilane | 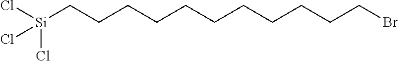 [SMILES: Cl[Si](Cl)(Cl)CCCCCCCCCCCBr] |
| 8 | 11-(2- methoxyethoxy)undecyltrichlorosilane | 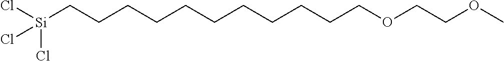 [SMILES: COCCOCCCCCCCCCCC[Si](Cl)(Cl)Cl] |
| 9 | 11-phenoxyundecyltrichlorosilane | 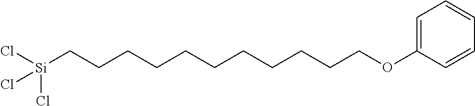 [SMILES: Cl[Si](Cl)(Cl)CCCCCCCCCCCOc1ccccc1] |
| 10 | 1,2-bis(trichlorosilyl)decane | 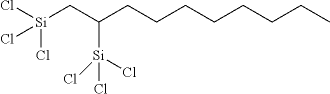 [SMILES: CCCCCCCCC(C[Si](Cl)(Cl)Cl)[Si](Cl)(Cl)Cl] |

In any embodiment, a compound corresponding in structure to Formula (I) can be delivered or exposed to a substrate (e.g., first substrate surface 15, second substrate surface 17, substrate 19, first substrate 25, second substrate 30) at a lower temperature. For example, such temperature may be less than or equal to about 185° C., less than or equal to about 175° C., less than or equal to about 150° C., less than or equal to about 140° C., less than or equal to about 130° C., less than or equal to about 120° C., less than or equal to about 110° C., or about 100° C.; or from about 100° C. to about 185° C., about 100° C. to about 175° C., about 100° C. to about 150° C., or about 100° C. to about 130° C.

In any embodiment, the second deposition process may include exposing a substrate (e.g., first substrate surface 15, second substrate surface 17, substrate 19, first substrate 25, second substrate 30) to at least one metal complex.

The metal complex may include a suitable metal center with one or more suitable ligands. Examples of a suitable metal center include, but are not limited to, titanium (Ti), zirconium (Zr) and hafnium (Hf). Examples of suitable ligands include but are not limited to, a C₁-C₁₀-alkyl group, a C₁-C₁₀-alkoxy group, a cyclopentadienyl group (Cp) optionally substituted with one or more C₁-C₁₀-alkyl group, and combinations thereof. For example, each ligand can independently be a methyl group, an ethyl group, a propyl group, a butyl group, methoxy group, an ethoxy group, a propoxy group, a butoxy group, a Cp group, a methyl substituted Cp (MeCp) group, an ethyl substituted Cp (EtCp) group, and combinations thereof

In some embodiments, the metal complex can correspond in structure to Formula II:

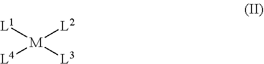

wherein M can be Ti, Zr, or Hf, particularly Hf; and L¹, L², L³, and L⁴ each independently can be selected from the group consisting of a C₁-C₈-alkyl group, a C₁-C₈-alkoxy group, and Cp group optionally substituted with at least one C₁-C₈-alkyl. In some embodiments L¹, L², L³, and L⁴ can all be the same.

In some embodiments, M can be Hf and L¹, L², L³, and L⁴ each independently can be selected from the group consisting of a C₁-C₄-alkyl group, a C₁-C₄-alkoxy group, and Cp group optionally substituted with at least one C₁-C₄-alkyl.

In some embodiments, M can be Hf and L¹, L², L³, and L⁴ each independently can be selected from the group consisting of a C₁-C₂-alkyl group, a C₁-C₂-alkoxy group, and Cp group optionally substituted with at least one C₁-C₂-alkyl.

In some embodiments, the metal complex can be (MeCp)₂Hf(OMe)(Me).

Advantageously, the metal of the metal-containing film can be present in a substantially small amount on the blocking layer or substantially not present on the blocking layer. For example, the metal of the metal-containing film may be present on the blocking layer in amount of less than or equal to about 25 at. %, less than or equal to about 20 at. %, less than or equal to about 15 at. %, less than or equal to about 10 at. %, less than or equal to about 5 at. %, less than or equal to about 1 at. %, less than or equal to about 0.5 at. % or about 0 at. %; or from about 0 at. % to about 25 at. %, about 0.5 at. % to about 25 at. %, about 0.5 at. % to about 20 at. %, about 0.5 at. % to about 15 at. %, about 0.5 at. % to about 10 at. % or about 1 at. % to about 5 at. %.

Additionally or alternatively, the blocking layer may be present in a small amount or substantially not present on the second substrate surface (or second portion of the substrate with a 100:1 selectivity).

As discussed above, the substrate may be exposed to a compound corresponding in structure to Formula I, a metal complex as described herein, or a combination thereof by any suitable deposition technique. For example, the first vapor deposition process may comprise vaporizing a compound corresponding in structure to Formula I. Additionally or alternatively, the second deposition process may comprise vaporing at least one metal complex as described herein.

For example, this may include (1) vaporizing a compound corresponding in structure to Formula I and/or vaporizing the at least one metal complex and (2) delivering the compound corresponding in structure to Formula I and/or delivering the at least one metal complex to a substrate surface (e.g., first substrate surface 15, second substrate surface 17, substrate 19, first substrate 25, second substrate 30), or passing the compound corresponding in structure to Formula I and/or passing the at least one metal complex over a substrate (and/or decomposing the compound corresponding in structure to Formula I and/or decomposing the at least one complex on the substrate surface).

Alternatively, the first liquid phase deposition process may comprise contacting a substrate surface (e.g., first substrate surface 15, second substrate surface 17, substrate 19, first substrate 25, second substrate 30) with a solution comprising the compound corresponding in structure to Formula (I). The solution may comprise any suitable solvent, such as a hydrocarbon or an amine solvent. Appropriate hydrocarbon solvents include, but are not limited to, aliphatic hydrocarbons, such as hexane, heptane and nonane; aromatic hydrocarbons, such as toluene and xylene; and aliphatic and cyclic ethers, such as diglyme, triglyme, and tetraglyme. Examples of appropriate amine solvents include, without limitation, octylamine and N,N-dimethyldodecylamine. For example, a compound corresponding in structure to Formula I may be dissolved in toluene to yield a solution with a concentration from about 0.01 M to about 1 M. In any embodiment, the first liquid phase deposition may include dipping or submerging a substrate (e.g., first substrate surface 15, second substrate surface 17, substrate 19, first substrate 25, second substrate 30) in the solution at least once for a suitable amount of time, for example, about 1 hour to about 36 hours, about 6 hours to about 30 hours, or about 12 hours to about 24 hours. Following contact with the solution, the coated substrate may then be dried.

In any embodiment, the first vapor deposition process and the second deposition process independently can be chemical vapor deposition (CVD) or atomic layer deposition (ALD).

The ALD and CVD methods encompass various types of ALD and CVD processes such as, but not limited to, continuous or pulsed injection processes, liquid injection processes, photo-assisted processes, plasma-assisted, and plasma-enhanced processes. For purposes of clarity, the methods of the present technology specifically include direct liquid injection processes. For example, in direct liquid injection CVD (“DLI-CVD”), a solid or liquid compound corresponding in structure to Formula I and/or metal complex may be dissolved in a suitable solvent and the solution formed therefrom injected into a vaporization chamber as a means to vaporize the compound corresponding in structure to Formula I and/or the metal complex. The vaporized compound corresponding in structure to Formula I and/or metal complex is then transported/delivered to the substrate surface. In general, DLI-CVD may be particularly useful in those instances where a metal complex displays relatively low volatility or is otherwise difficult to vaporize.

In one embodiment, conventional or pulsed CVD is used to form a metal-containing film by vaporizing and/or passing the at least one metal complex over a substrate surface. Additionally or alternatively, conventional or pulsed CVD is used to deliver a compound corresponding in structure to Formula I by vaporizing and/or passing the compound corresponding in structure to Formula I over a substrate surface. For conventional CVD processes see, for example Smith, Donald (1995). Thin-Film Deposition: Principles and Practice. McGraw-Hill.

In one embodiment, CVD growth conditions for the compound corresponding in structure to Formula I and/or the metal complexes disclosed herein include, but are not limited to:
a) Substrate temperature: 50-600° C.
b) Evaporator temperature (metal precursor temperature): 0-200° C.
c) Reactor pressure: 0-100 Torr
d) Argon or nitrogen carrier gas flow rate: 0-500 sccm
e) Oxygen flow rate: 0-500 sccm
f) Hydrogen flow rate: 0-500 sccm
g) Run time: will vary according to desired film thickness

In another embodiment, photo-assisted CVD is used to form a metal-containing film by vaporizing and/or passing at least one metal complex disclosed herein over a substrate surface. Additionally or alternatively, photo-assisted CVD is used to deliver a compound corresponding in structure to Formula I by vaporizing and/or passing the compound corresponding in structure to Formula I over a substrate surface.

In a further embodiment, conventional (i.e., pulsed injection) ALD is used to form a metal-containing film by vaporizing and/or passing at least one metal complex disclosed herein over a substrate surface. Additionally or alternatively, conventional (i.e., pulsed injection) ALD used to deliver a compound corresponding in structure to Formula I by vaporizing and/or passing the compound corresponding in structure to Formula I over a substrate surface. For conventional ALD processes see, for example, George S. M., et al. J. Phys. Chem., 1996, 100, 13121-13131.

In another embodiment, liquid injection ALD is used to form a metal-containing film by vaporizing and/or passing at least one metal complex disclosed herein over a substrate surface, wherein at least one metal complex is delivered to the reaction chamber by direct liquid injection as opposed to vapor draw by a bubbler. Additionally or alternatively, liquid injection ALD is used to deliver a compound corresponding in structure to Formula I by vaporizing and/or passing the compound corresponding in structure to Formula I over a substrate surface, wherein the compound corresponding in structure to Formula I is delivered to the reaction chamber by direct liquid injection as opposed to vapor draw by a bubbler. For liquid injection ALD processes see, for example, Potter R. J., et al., Chem. Vap. Deposition, 2005, 11(3), 159-169.

Examples of ALD growth conditions for metal complexes disclosed herein include, but are not limited to:
a) Substrate temperature: 0-400° C.
b) Evaporator temperature (metal precursor temperature): 0-200° C.
c) Reactor pressure: 0-100 Torr
d) Argon or nitrogen carrier gas flow rate: 0-500 sccm
e) Reactive gas flow rate: 0-500 sccm
f) Pulse sequence (metal complex/purge/reactive gas/purge): will vary according to the optimized process conditions and chamber size
g) Number of cycles: will vary according to desired film thickness

In another embodiment, photo-assisted ALD is used to form a metal-containing film by vaporizing and/or passing at least one metal complex disclosed herein over a substrate surface. Additionally or alternatively, photo-assisted ALD is used to deliver a compound corresponding in structure to Formula I by vaporizing and/or passing the compound corresponding in structure to Formula I over a substrate surface. For photo-assisted ALD processes see, for example, U.S. Pat. No. 4,581,249.

In another embodiment, plasma-assisted or plasma-enhanced ALD is used to form a metal-containing film by vaporizing and/or passing at least one metal complex disclosed herein over a substrate surface. Additionally or alternatively, plasma-assisted or plasma-enhanced ALD is used to deliver a compound corresponding in structure to Formula I by vaporizing and/or passing the compound corresponding in structure to Formula I over a substrate surface.

In another embodiment, a method of forming a metal-containing film on a substrate surface comprises: during an ALD process, exposing a substrate to a vapor phase metal complex according to one or more of the embodiments described herein, such that a layer is formed on the surface comprising the metal complex bound to the surface by the metal center (e.g., hafnium); during an ALD process, exposing the substrate having bound metal complex with a co-reactant such that an exchange reaction occurs between the bound metal complex and co-reactant, thereby dissociating the bound metal complex and producing a first layer of elemental metal on the surface of the substrate; and sequentially repeating the ALD process and the treatment.

The reaction time, temperature and pressure are selected to create a metal-surface interaction and achieve a layer on the surface of the substrate. The reaction conditions for the ALD reaction will be selected based on the properties of the metal complex. The deposition can be carried out at atmospheric pressure but is more commonly carried out at a reduced pressure. The vapor pressure of the metal complex should be low enough to be practical in such applications. The substrate temperature should be high enough to keep the bonds between the metal atoms at the surface intact and to prevent thermal decomposition of gaseous reactants. However, the substrate temperature should also be high enough to keep the source materials (i.e., the reactants) in the gaseous phase and to provide sufficient activation energy for the surface reaction. The appropriate temperature depends on various parameters, including the particular metal complex used and the pressure. The properties of a specific metal complex for use in the ALD deposition methods disclosed herein can be evaluated using methods known in the art, allowing selection of appropriate temperature and pressure for the reaction. In general, lower molecular weight and the presence of functional groups that increase the rotational entropy of the ligand sphere result in a melting point that yields liquids at typical delivery temperatures and increased vapor pressure.

A metal complex for use in the deposition methods will have all of the requirements for sufficient vapor pressure, sufficient thermal stability at the selected substrate temperature and sufficient reactivity to produce a reaction on the surface of the substrate without unwanted impurities in the thin film. Sufficient vapor pressure ensures that molecules of the source compound are present at the substrate surface in sufficient concentration to enable a complete self-saturating reaction. Sufficient thermal stability ensures that the source compound will not be subject to the thermal decomposition which produces impurities in the thin film.

Thus, the metal complexes disclosed herein utilized in these methods may be liquid, solid, or gaseous. Typically, the metal complexes are liquids or solids at ambient temperatures with a vapor pressure sufficient to allow for consistent transport of the vapor to the process chamber.

In certain embodiments, the metal-containing complex and/or the compound corresponding in structure to Formula I may be dissolved in a suitable solvent such as a hydrocarbon or an amine solvent to facilitate the vapor deposition process. Appropriate hydrocarbon solvents include, but are not limited to, aliphatic hydrocarbons, such as hexane, heptane and nonane; aromatic hydrocarbons, such as toluene and xylene; and aliphatic and cyclic ethers, such as diglyme, triglyme, and tetraglyme. Examples of appropriate amine solvents include, without limitation, octylamine and N,N-dimethyldodecylamine. For example, the metal-containing complex may be dissolved in toluene to yield a solution with a concentration from about 0.05 M to about 1 M.

In another embodiment, the at least one metal complex and/or the compound corresponding in structure to Formula I may be delivered “neat” (undiluted by a carrier gas) to a substrate surface.

In another embodiment, a mixed-metal film can be formed by the methods described herein which vaporizes at least a first metal complex as disclosed herein in combination, but not necessarily at the same time, with a second metal complex comprising a metal other than that of the first metal complex disclosed herein (and/or with a third metal complex and/or with a fourth metal complex and so on). For example, the first metal complex can comprise Hf and the second metal-containing complex can comprise Zr to form a mixed-metal, Hf—Zr film. In some embodiments, the mixed-metal film may be a mixed-metal oxide, a mixed-metal nitride, or a mixed-metal oxy-nitride.

In one embodiment, an elemental metal, a metal nitride, a metal oxide, or a metal silicide film can be formed by delivering for deposition at least one metal complex as disclosed herein, independently or in combination with a co-reactant. In this regard, the co-reactant may be deposited or delivered to or passed over a substrate surface, independently or in combination with the at least one metal complex. As will be readily appreciated, the particular co-reactant used will determine the type of metal-containing film is obtained. Examples of such co-reactants include, but are not limited to hydrogen, hydrogen plasma, oxygen, air, water, an alcohol, H₂O₂, N₂O, ammonia, a hydrazine, a borane, a silane, ozone, or a combination of any two or more thereof. Examples of suitable alcohols include, without limitation, methanol, ethanol, propanol, isopropanol, tert-butanol, and the like. Examples of suitable boranes include, without limitation, hydridic (i.e., reducing) boranes such as borane, diborane, triborane and the like. Examples of suitable silanes include, without limitation, hydridic silanes such as silane, disilane, trisilane, and the like. Examples of suitable hydrazines include, without limitation, hydrazine (N₂H₄), a hydrazine optionally substituted with one or more alkyl groups (i.e., an alkyl-substituted hydrazine) such as methylhydrazine, tert-butylhydrazine, N,N- or N,N′-dimethylhydrazine, a hydrazine optionally substituted with one or more aryl groups (i.e., an aryl-substituted hydrazine) such as phenylhydrazine, and the like.

In one embodiment, the metal complexes disclosed herein are delivered to the substrate surface in pulses alternating with pulses of an oxygen-containing co-reactant as to provide metal oxide films. Examples of such oxygen-containing co-reactants include, without limitation, H₂O, H₂O₂, O₂, ozone, air, i-PrOH, t-BuOH, or N₂O.

In other embodiments, a co-reactant comprises a reducing reagent such as hydrogen. In such embodiments, an elemental metal film is obtained. In particular embodiments, the elemental metal film consists of, or consists essentially of, pure metal. Such a pure metal film may contain more than about 80, 85, 90, 95, or 98% metal. In even more particular embodiments, the elemental metal film is a hafnium film.

In other embodiments, a co-reactant is used to form a metal nitride film by delivering for deposition at least one metal complex as disclosed herein, independently or in combination, with a co-reactant such as, but not limited to, ammonia, a hydrazine, and/or other nitrogen-containing compounds (e.g., an amine) to a reaction chamber. A plurality of such co-reactants may be used. In further embodiments, the metal nitride film is a hafnium nitride film.

In a particular embodiment, the methods of the present technology are utilized for applications such as dynamic random access memory (DRAM) and complementary metal oxide semi-conductor (CMOS) for memory and logic applications, on substrates such as silicon chips.

Any of the metal complexes disclosed herein may be used to prepare thin films of the elemental metal, metal oxide, metal nitride, and/or metal silicide. Such films may find application as oxidation catalysts, anode materials (e.g., SOFC or LIB anodes), conducting layers, sensors, diffusion barriers/coatings, super- and non-superconducting materials/coatings, tribological coatings, and/or, protective coatings. It is understood by one of ordinary skill in the art that the film properties (e.g., conductivity) will depend on a number of factors, such as the metal(s) used for deposition, the presence or absence of co-reactants and/or co-complexes, the thickness of the film created, the parameters and substrate employed during growth and subsequent processing.

Reference throughout this specification to “one embodiment,” “certain embodiments,” “one or more embodiments” or “an embodiment” means that a particular feature, structure, material, or characteristic described in connection with the embodiment is included in at least one embodiment of the present technology. Thus, the appearances of the phrases such as “in one or more embodiments,” “in certain embodiments,” “in one embodiment” or “in an embodiment” in various places throughout this specification are not necessarily referring to the same embodiment of the present technology. Furthermore, the particular features, structures, materials, or characteristics may be combined in any suitable manner in one or more embodiments.

Although the present technology herein has been described with reference to particular embodiments, it is to be understood that these embodiments are merely illustrative of the principles and applications of the present technology. It will be apparent to those skilled in the art that various modifications and variations can be made to the method and apparatus of the present technology without departing from the spirit and scope of the present technology. Thus, it is intended that the present technology include modifications and variations that are within the scope of the appended claims and their equivalents. The present technology, thus generally described, will be understood more readily by reference to the following examples, which is provided by way of illustration and is not intended to be limiting.

### EXAMPLES

### Example 1: Formation of Blocking Layers by Liquid Phase Deposition and Blocking Layer Inhibition of Hafnium-Containing Films

Compounds of Formula (I) were mixed with toluene to form Solutions 1-10, as shown in Table 2 below.

TABLE 2

| Solution | |
|---|---|
| (10 mM) | Components |
| 1 | n-octyltrichlorosilane + toluene |
| 2 | dodecyltrichlorosilane + toluene |
| 3 | 11-cyanoundecyltrichlorosilane + toluene |
| 4 | 11-acetoxyundecyltrichlorosilane + toluene |
| 5 | (tridecafluoro-1,1,2,2-tetrahydrooxtyl) |
| | trichlorosilane + toluene |
| 6 | 10-undecenyltrichlorosilane + toluene |
| 7 | 11-bromoundecyltrichlorosilane + toluene |
| 8 | 11-(2-methoxyethoxy)undecyltrichlorosilane + |
| | toluene |
| 9 | 11-phenoxyundecyltrichlorosilane + toluene |
| 10 | 1,2-bis(trichlorosilyl)decane + toluene |

Blocking layers were prepared by a liquid phase delivery method, i.e., a dipping method, which involved dipping Si coupons in Solutions 1-10 for 24 hours inside a glovebox to form Coated Coupons 1-10, respectively. After 24 hours, the Coated Coupons 1-10 were rinsed in toluene inside the glovebox and rinsed in acetone and dichloromethane inside a chemical hood. The Coated Coupons 1-10 were dried using N₂ and characterized with ellipsometry and water contact angle measurements.

The ability of blocking layers formed on Coated Coupons 1-10 to inhibit growth of Hf-containing films was then tested. Each of the Coated Coupons 1-10 were loaded into an ALD chamber and tested for 50, 100, 200 and 300 cycles of (MeCp)₂Hf(OMe)(Me) and H₂O in separate trials. For the control, Si coupons were only exposed to (MeCp)₂Hf(OMe)(Me). The HfO ALD process conditions were as follows: 2 seconds pulse (MeCp)₂Hf(OMe)(Me), 10 seconds pulse N₂, 2 seconds pulse H₂O, and 10 seconds pulse N₂ at 350° C. Solution 3 containing 11-cyanoundecyltrichlorosilane showed the highest blocking for 200 cycles. Coated Coupon 3 treated with Solution 3 showed the lowest HfO₂ thickness after exposure to 200 cycles.

### Example 2: Formation of Blocking Layers by Vapor Phase Deposition and Blocking Layer Inhibition of Hafnium-Containing Films

Compound 1 (n-octyltrichlorosilane), Compound 2 (dodecyltrichlorosilane), and Compound 3 (11-cyanoundecyltrichlorosilane) were delivered via vapor draw to silicon substrates to form Coated Substrates 1-3, respectively. The ampoule temperatures were 120° C. for Compound 1, 160° C. for Compound 2, and 185° C. for Compound 3.

The ability of blocking layers formed on Coated Substrates 1-3 to inhibit growth of Hf-containing films was then tested. Each of the Coated Substrates 1-3 were loaded into an ALD chamber and tested for 50, 100, 200, 300, and 400 cycles of (MeCp)₂Hf(OMe)(Me) and H₂O in separate trials. For the control, Si coupons were only exposed to (MeCp)₂Hf(OMe)(Me). The HfO ALD process conditions were as follows: 2 seconds pulse (MeCp)₂Hf(OMe)(Me), 10 seconds pulse N₂, 2 seconds pulse H₂O, and 10 seconds pulse N₂ at 350° C.

All publications, patent applications, issued patents and other documents referred to in this specification are herein incorporated by reference as if each individual publication, patent application, issued patent, or other document was specifically and individually indicated to be incorporated by reference in its entirety. Definitions that are contained in text incorporated by reference are excluded to the extent that they contradict definitions in this disclosure.

The words “comprise”, “comprises”, and “comprising” are to be interpreted inclusively rather than exclusively.

1. A method of forming a metal-containing film, the method comprising:
forming a blocking layer on a first substrate surface by a first vapor phase deposition process or a first liquid phase deposition process,
wherein the first vapor phase deposition process comprises vaporizing a compound corresponding in structure to Formula (I): 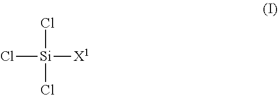
wherein
X¹ is R¹ or R²R³; wherein R¹ is a C₁-C₂₀-alkyl, optionally substituted with one or more trichlorosilyl group; R² is a C₁-C₂₀-alkylene group optionally substituted with one or more halogen; and R³ is selected from the group consisting of a nitrile group, an ethenyl group, a halogen, a triflouromethyl group, an acetoxy group, a methoxyethoxy group, and a phenoxy group; and
wherein the first liquid phase deposition process comprises contacting the first substrate surface with a solution comprising the compound corresponding in structure to Formula (I); and
forming the metal-containing film on a second substrate surface by a second deposition process, the second deposition process comprising vaporizing at least one metal complex corresponding in structure to Formula II: 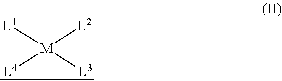
wherein M is Hf; and
L¹, L², L³, and L⁴ are each independently selected from the group consisting of a C₁-C₈-alkyl group, a C₁-C₈-alkoxy group, and a Cp group optionally substituted with at least one C₁-C₈-alkyl;
wherein the first substrate surface comprises a dielectric material or a metal oxide material and the second substrate surface comprises a metal material.

2. A method of forming a metal-containing film, the method comprising:
forming a blocking layer on a first portion of a substrate by a first vapor phase deposition process or a first liquid phase deposition process,
wherein the first vapor phase deposition process comprises vaporizing a compound corresponding in structure to Formula (I): 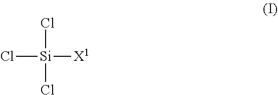
wherein
X¹ is R¹ or R²R³; wherein R¹ is a C₁-C₂₀-alkyl, optionally substituted with one or more trichlorosilyl group; R² is a C₁-C₂₀-alkylene group optionally substituted with one or more halogen; and R³ is selected from the group consisting of a nitrile group, an ethenyl group, a halogen, a triflouromethyl group, an acetoxy group, a methoxyethoxy group, and a phenoxy group; and
wherein the first liquid phase deposition process comprises contacting the first portion of the substrate with a solution comprising the compound corresponding in structure to Formula (I); and
forming the metal-containing film on a second portion of the substrate by a second deposition process, the second deposition process comprising vaporizing at least one metal complex corresponding in structure to Formula II: 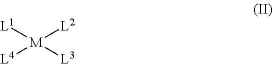
wherein M is Hf; and
L¹, L², L³, and L⁴ are each independently selected from the group consisting of a C₁-C₈-alkyl group, a C₁-C₈-alkoxy group, and a Cp group optionally substituted with at least one C₁-C₈-alkyl;
wherein the first portion of the substrate comprises a dielectric material or a metal oxide material and the second portion of the substrate comprises a metal material.

3. (canceled)

4. The method of claim 1, wherein R¹ is a C₁-C₁₂-alkyl, each optionally substituted with one or more of a trichlorosilyl group and/or wherein R² is a C₁-C₁₂-alkylene.

5. (canceled)

6. (canceled)

7. The method of claim 1, wherein the compound corresponding in structure to Formula (I) is selected from the group consisting of:
n-octyltrichlorosilane;
dodecyltrichlorsilane;
11-cyanoundecyltrichlorosilane;
11-acetoxyundecyltrichlorosilane;
(tridecafluoro-1,1,2,2-tetrahydrooxtyl)trichlorosilane;
10-undecenyltrichlorosilane;
11-bromoundecyltrichlorosilane;
11-(2-methoxyethoxy)undecyltrichlorosilane;
11-phenoxyundecyltrichlorosilane; and
1,2-bis(trichlorosilyl)decane.

8. (canceled)

9. The method of claim 1, wherein the metal complex is (MeCp)₂Hf(OMe)(Me).

10. The method of claim 1, wherein the metal of the metal-containing film is present in an amount of less than about 15 at. % on the blocking layer.

11. The method of claim 1, wherein the first substrate surface and the second substrate surface are present on the same substrate or on different substrates.

12. The method of claim 1, wherein the metal material comprises W, Co, Cu or a combination thereof, the dielectric material comprises SiO₂, SiN, or a combination thereof, or the metal oxide material comprises HfO₂, ZrO₂, SiO₂, Al₂O₃, or a combination thereof.

13. (canceled)

14. The method of claim 1, wherein first vapor phase deposition process and the second deposition process are independently chemical vapor deposition or atomic layer deposition, wherein the chemical vapor deposition is pulsed chemical vapor deposition, continuous flow chemical vapor deposition, or liquid injection chemical vapor deposition, and wherein the atomic layer deposition is liquid injection atomic layer deposition or plasma-enhanced atomic layer deposition.

15. (canceled)

16. (canceled)

17. The method of claim 1, wherein the first liquid phase deposition process comprises dipping the first substrate surface or the first portion of the substrate surface in the solution comprising the compound of Formula (I) one or more times.

18. The method of claim 1, wherein the metal complex is delivered to a substrate in pulses alternating with pulses of an oxygen source wherein the oxygen source is selected from the group consisting of H₂O, H₂O₂, ozone, air, i-PrOH, t-BuOH, and N₂O.

19. (canceled)

20. The method of claim 1, further comprising vaporizing at least one co-reactant selected from the group consisting of hydrogen, hydrogen plasma, oxygen, air, water, ammonia, a hydrazine, a borane, a silane, ozone, and a combination of any two or more thereof.

21. (canceled)

22. The method of claim 2, wherein R¹ is a C₁-C₁₂-alkyl, each optionally substituted with one or more of a trichlorosilyl group and/or wherein R² is a C₁-C₁₂-alkylene.

23. The method of claim 2, wherein the compound corresponding in structure to Formula (I) is selected from the group consisting of:
n-octyltrichlorosilane;
dodecyltrichlorsilane;
11-cyanoundecyltrichlorosilane;
11-acetoxyundecyltrichlorosilane;
(tridecafluoro-1,1,2,2-tetrahydrooxtyl)trichlorosilane;
10-undecenyltrichlorosilane;
11-bromoundecyltrichlorosilane;
11-(2-methoxyethoxy)undecyltrichlorosilane;
11-phenoxyundecyltrichlorosilane; and
1,2-bis(trichlorosilyl)decane.

24. The method of claim 2, wherein the metal complex is (MeCp)₂Hf(OMe)(Me).

25. The method of claim 2, wherein the metal of the metal-containing film is present in an amount of less than about 15 at. % on the blocking layer.

26. The method of claim 2, wherein the metal material comprises W, Co, Cu or a combination thereof, the dielectric material comprises SiO₂, SiN, or a combination thereof, or the metal oxide material comprises HfO₂, ZrO₂, SiO₂, Al₂O₃, or a combination thereof.

27. The method of claim 2, wherein first vapor phase deposition process and the second deposition process are independently chemical vapor deposition or atomic layer deposition, wherein the chemical vapor deposition is pulsed chemical vapor deposition, continuous flow chemical vapor deposition, or liquid injection chemical vapor deposition, and wherein the atomic layer deposition is liquid injection atomic layer deposition or plasma-enhanced atomic layer deposition.

28. The method of claim 2, wherein the first liquid phase deposition process comprises dipping the first substrate surface or the first portion of the substrate surface in the solution comprising the compound of Formula (I) one or more times.

29. The method of claim 2, wherein the metal complex is delivered to a substrate in pulses alternating with pulses of an oxygen source, wherein the oxygen source is selected from the group consisting of H₂O, H₂O₂, O₂, ozone, air, i-PrOH, t-BuOH, and N₂O.

30. The method of claim 2, further comprising vaporizing at least one co-reactant selected from the group consisting of hydrogen, hydrogen plasma, oxygen, air, water, ammonia, a hydrazine, a borane, a silane, ozone, and a combination of any two or more thereof.
